(19) United States
(12) Patent Application Publication
(10) Pub. No.: US 2010/0005857 A1
(43) Pub. Date: Jan. 14, 2010

(54) Interactive mobile aquatic probing and surveillance system

(75) Inventors: Hong Zhang, Metuchen, NJ (US); Ying Tang, Glassboro, NJ (US); Patricia Mosto, Pitman, NJ (US); Courtney E. Richmond, Glassboro, NJ (US)

Correspondence Address: JOHN F. LETCHFORD, ARCHER & GREINER, P.C., ONE CENENNIAL SQUARE, HADDONFIELD, NJ, 08033, US

(73) Assignee: Rowan University, Glassboro, NJ (US)

(21) Appl. No.: 11/796,741

(22) Filed: Apr. 27, 2007

Related U.S. Application Data
(60) Provisional application No. 60/795,758, filed on Apr. 28, 2006.

(51) Int. Cl. G01C 13/00; G01W 1/14; G01N 19/10; B01J 19/00; G01R 29/00

(52) U.S. Cl. 73/29.02; 73/170.29; 73/170.17; 422/68.1; 324/722

(57) ABSTRACT

An Interactive Mobile Aquatic Probing and Surveillance system. The system includes a remote aquatic or amphibious agent which is controlled by a typically land-based computer host. The agent is a field robot in the form of a comparatively small and inexpensive, untethered, self-propelled, aquatic or amphibious, non-submersible vehicle that preferably carries physical and water characteristic sensors, as well as other operational equipment for use on relatively small bodies of water and wetlands. The host interacts with a human operator and provides control commands to and receives data from the agent in real time via a wireless communication between the agent and the host. The control commands include guidance commands including navigational and propulsion commands as well as commands for operating the sensors and various other equipment carried by the agent.

### CROSS REFERENCE TO RELATED APPLICATION

The present application claims the benefit of U.S. Provisional Patent Application No. 60/795,758, filed Apr. 28, 2006, which is incorporated herein in its entirety by reference thereto.

### FIELD OF THE INVENTION

The present invention relates in general to aquatic probing systems and in particular to economical systems for probing the characteristics of relatively shallow bodies of water and wetlands.

### BACKGROUND OF THE INVENTION

Shallow water and wetland habitats are among the most productive and ecologically significant habitats in nature. Estimates of primary production in estuaries of >2000 g dry wt C m⁻² yr⁻¹ and in marshes of up to 2900 g dry wt C m⁻² yr⁻¹ are comparable to rainforests. Wetlands also provide a variety of economic goods and services such as water filtration, coastal protection, habitat provision, and food production with a value estimated in 1997 of nearly $10,000 ha⁻¹ yr⁻¹ (˜$1.650 trillion, globally).

Despite their ecological and economic importance shallow water and wetland habitats are threatened by a variety of anthropogenic and natural phenomena. For example, global wetland loss has been estimated to be at least 50% from its original state. While draining and filling of wetlands to create usable uplands is a primary cause of this loss, natural processes such as subsidence, drought, storms, and sea-level rise can also result in loss of important wetlands. Water quality in many aquatic habitats is in decline due to increased development, hydrologic modification, and non-point source pollution. As a result, vulnerable species can be displaced. A classic example is that of seagrass populations. Some shallow water seagrasses can serve as indicators of upstream estuarine water quality and ecosystem health. As such, accurate monitoring and predicting of seagrass population dynamics can also serve as a proxy for the environmental condition of a greater region. Seagrass populations have been declining in density and spatial distribution as anthropogenic activities in the coastal zone have increased worldwide. A proximate cause of this loss is reduction in light penetration due to coastal development, mechanical damage (e.g., from propeller scarring, anchoring and dredging), algal blooms and over-water construction such as docks.

The loss of seagrass habitats worldwide has a cascading effect due to the many ecosystem services they provide. They not only provide sustenance for a number of benthic-feeding organisms including sea turtles, manatees, and sea urchins, but also stabilize sediments in coastal regions and provide physical refuge for a number of benthic organisms. As seagrass beds decline, the biodiversity of both resident species (e.g., hermit crabs, sea urchins, snails and meiofauna) and transient species (e.g., sea turtles, manatees and benthic-feeding fishes) is negatively impacted. For this reason, it is critical to further human understanding of the factors contributing to seagrass losses, in order to de-list threatened and endangered species such as, for example, Halophila johnsonii (“H. johnsonii”), among many others, and to prevent other species from being listed as threatened or endangered.

A variety of methods and equipment are used to study water quality and related ecosystems. Some methods involve simple human empirical observation and manual data gathering. At the opposite extreme, a variety of highly sophisticated and expensive equipment has been developed to study aquatic systems. For example, Remotely Operated Vehicles (ROVs) and Autonomous Underwater Vehicles (AUVs) have revolutionized exploration of the oceans and deep lakes by permitting unmanned access to remote habitats and by autonomously performing underwater testing and related tasks.

ROVs are unmanned submersible vessels that receive power and communication from a launching vessel or mother ship. Although they may be untethered, these vehicles typically are tethered to the mother ship and provide safe and effective access to habitats that are difficult or impossible for humans to reach. They are generally quite expensive due to the need for a launching vessel and the involvement of a human operator as well as for specialized components that are needed to withstand water pressure at great depth. And, because ROVs are tethered to a mother ship, the reach of their umbilical or tether limits their range of operation. Moreover, underwater obstructions, rough seas or uncompensated loads can damage the tether which can result in loss of communication and power. These limitations generally prohibit the application of ROVs in shallow waters or over complex terrain.

AUVS, as their name indicates, are capable of autonomous deployment. They are relatively self-contained and do not require constant attention from a shipboard operator. AUVs are generally superior to ROVs in that they typically offer better mapping capabilities, improved logistics, and more effective utilization of the surface support vessel. In addition, AUVs are intended to mimic the maneuverability of aquatic animals and span the dynamic range necessary for observing the spatial and temporal scales of ocean processes.

However, the autonomous nature of AUVs presents certain disadvantages. Many AUVs are fully autonomous. Fully autonomous AUVs cannot provide real-time telemetry of vehicle condition, status, or scientific data. They also lack means for controlling or redirecting the vehicle during a mission. Therefore, even a minor failure of the vehicle can result in catastrophic loss. And, underwater obstructions, shallow depths and complex terrain present further problems for AUVs, regardless of whether they are fully partially autonomous.

U.S. Pat. No. 5,995,882 describes an AUV that may operate under tethered or untethered conditions. The AUV conveys detected aquatic information to a land base in real time and may employ GPS technology.

U.S. Pat. Nos. 5,687,137 and 5,894,450 describe systems for deploying and monitoring the activities of an array of untethered AUVs. The AUVs acoustically communicate with network nodes in the form of a plurality of anchored buoys which in turn communicate in real-time, near real-time or in delayed time with a remote land or shore-based central system. Water temperature, depth, salinity and unidentified “externally sensed parameters” are among the aquatic parameters that these patents list as possible characteristics that may be sensed by the AUV sensors.

U.S. Pat. Nos. 6,187,530; 6,561,046 and 7,071,466 and published U.S. Patent Application Nos. 2002/0079442 and 2005/0030015 describe various tethered and untethered AUVs and/or ROVs for detecting and communicating in real-time water quality and other data, including without limitation, water temperature, depth, conductivity, dissolved oxygen, pH, CO₂, nitrates, nitrites, nitrogen, total phosphorous, heavy metals and petroleum by-products.

Published U.S. Patent Application Nos. 2006/0008137 and 2006/0152589 describe UAV and/or ROV devices for visually inspecting underwater objects and structures via cameras.

U.S. Pat. Nos. 6,269,763 and 6,349,665 disclose multifunction AUVs/drones.

U.S. Pat. Nos. 6,118,066; and 7,007,625 and 7,077,072 variously describe tethered and untethered AUVs, ROVs and unmanned underwater vehicles (“UUVs”).

Because ROVs and AUVs have traditionally been designed for use in deep lakes, seas and ocean environments, their developers have been focused primarily on reaching greater depths. However, improvements in materials technology and acceptance of these vehicles for usage in other than deep water applications have resulted in some measure of miniaturization and application to other habitats (e.g., water depths of less than 12 m). Nevertheless, submersible ROVs and AUVs remain prohibitively expensive for many businesses, researchers, municipalities, governmental agencies and others interested in accurate water quality assessments of shallow bodies of water.

Ecological studies of shallow water and wetland habitats are often hindered by difficulties in accessing remote sites. In addition, current methods of data acquisition in shallow-water and wetland habitats are ill suited for capturing high-resolution data continuously in time and space. For example, physical sampling at worker-selected locations in the field offers limited sampling stations and numbers of observations (i.e., the sampling may be semi-continuous to substantially continuous in space but discrete in time). Such methods are sensitive to environmental and logistical conditions (e.g., season, weather, terrain and accessibility) which may influence and potentially limit the choice of sampling times and sites.

In contrast to this method, unmanned sensors can be mounted in the field. This practice enables continuous monitoring of specific, static locations (i.e., the sampling is continuous in time but discrete in space). The semi-permanent to permanent deployment of sensors in the field can physically alter the surrounding environment by their presence, and the cost of this option multiplies quickly with the number of stations deployed. An example of such a system is the “6951 Profiler” marketed by YSI Incorporated of Yellow Springs, Ohio. The “6951 Profiler” is a large, pontoon-based apparatus that can support the weight of a human adult. It is towed by a boat to a desired water site to be monitored and anchored at that site and can monitor only the water in a single vertical column beneath the pontoon.

For different reasons, both physical sampling and unmanned sampling regimes lack the flexibility that is critical to characterizing conditions or organisms in dynamic habitats. Existing mobile sensor platforms such as ROVs and AUVs are capable of dynamic remote data collection. However, presently existing miniaturized versions of these vehicles are expensive, have limited agility and are not suitable for work in very shallow water or the complex terrain of wetland habitats.

An advantage exists, therefore, for an apparatus that is capable of remote deployment in bodies of water as shallow as or even less than 1 m deep and in wetland habitats whereby researchers and others may accurately and reliably study shallow water, intertidal, and wetlands systems.

A further advantage exists for a robust, cost-effective and flexible solution for extended, real-time, continuous and interactive data collection in shallow water and wetlands habitats that are currently inaccessible to existing mobile aquatic sampling technologies.

### SUMMARY OF THE INVENTION

The intrinsic ecological and economic value of wetland and shallow water habitats, and the pervasive threats to these habitats, places a premium on research that examines their functioning, interconnections, and their role in regional and global ecosystems. New tools are therefore required to gain access to habitats that are characterized by shallow water, saturated organic soils, and high-percent cover of vegetation. To address these needs, the present invention provides an interactive aquatic or amphibious vehicle which is capable of collecting water quality and geospatial data that will allow researchers to sample shallow waters and wetlands in a manner not possible with traditional means.

In this regard, the present invention provides an Interactive Mobile Aquatic Probing and Surveillance (IMAPS) system. The system includes a remote aquatic or amphibious agent which is controlled by a typically land-based computer host. The agent is a field robot in the form of a comparatively small and inexpensive, untethered, self-propelled, aquatic or amphibious, non-submersible vehicle that preferably carries physical and biological sensors for use on relatively small bodies of water and wetlands. The host interacts with a human operator and provides control commands to and receives data from the agent in real time via a wireless communication between the agent and the host. The control commands include guidance commands including navigational and propulsion commands as well as commands for operating various equipment and sensors carried by the agent.

In a water testing operation, the agent cruises on the water surface and performs requested tests of water quality according to the control commands transmitted by the host. When testing, the agent remains on the water's surface and lowers a sensor or sensors into the water while transmitting detected data to the host. In certain respects the IMAPS system represents a cross between an ROV and an AUV. That is, like an ROV, it is telemetrically-operated from a distant host and communication between the host and the agent is continuous. And, in a manner similar to an AUV, the host computer can be pre-programmed to generate algorithms to autonomously control the agent to obtain underwater information and to autonomously navigate the agent (for path planning, obstacle avoidance, and the like)—although the agent may alternatively be controlled by a human operator.

In addition to propulsion and guidance mechanisms, the equipment carried by the agent may include: one or more cameras that visually monitor areas surrounding the agent, one or more water characteristic sensors (and means for deploying same) including physical sensors for detecting water temperature and depth, and one or more water quality sensors for detecting such “bio-related” water characteristics as dissolved oxygen and nitrogen, pH, algae concentration, turbidity, and so on.

Other details, objects and advantages of the present invention will become apparent as the following description of the presently preferred embodiments and presently preferred methods of practicing the invention proceeds.

### BRIEF DESCRIPTION OF THE DRAWINGS

The invention will become more readily apparent from the following description of preferred embodiments thereof shown, by way of example only, in the accompanying drawings wherein:

FIG. 1 is a multi-graph display of water characteristic data from Houma, La. conducted during year 2005;

FIG. 2 is a block diagram of an agent of an interactive mobile aquatic probing and surveillance system according to the present invention;

FIG. 3 is a block diagram of a host of an interactive mobile aquatic probing and surveillance system according to the present invention;

FIG. 4 is a front perspective view, with certain elements omitted for clarity of illustration, of a first embodiment of an agent of an interactive mobile aquatic probing and surveillance system according to the present invention;

FIG. 5 is a rear perspective view, with certain elements omitted for clarity of illustration, of a further embodiment of an agent of an interactive mobile aquatic probing and surveillance system according to the present invention;

FIG. 6 is a top perspective view of the agent of FIG. 5;

FIG. 7 is a side view of the agent of FIG. 5 floating on the surface of a body of water with a water characteristic sensor depending therefrom in a position to detect one or more water characteristics at a desired underwater location;

FIG. 8 is a side view of the agent of FIG. 5 in contact with a land surface beneath the surface of a body of water with a water characteristic sensor depending therefrom;

FIG. 9 is a top perspective view of a further embodiment of an agent of an interactive mobile aquatic probing and surveillance system according to the present invention with a cover thereof omitted to clearly illustrate the internal structure and major electrical and mechanical components thereof;

FIG. 10 is a bottom-rear perspective view of the agent of FIG. 9;

FIG. 11 is a bottom-front perspective view of the agent of FIG. 9;

FIG. 12 is a perspective view of a sensor holder of an interactive mobile aquatic probing and surveillance system according to the present invention;

FIG. 13 is a perspective view of a host of an interactive mobile aquatic probing and surveillance system according to the present invention;

FIG. 14 is a depiction of representative information that may be displayed by a graphical user interface screen of the host of an interactive mobile aquatic probing and surveillance system according to the present invention;

FIG. 15 is a depiction of other representative information that may be displayed by a graphical user interface screen of the host of an interactive mobile aquatic probing and surveillance system according to the present invention; and

FIG. 16 is a depiction of other representative information that may be displayed by a graphical user interface screen of the host of an interactive mobile aquatic probing and surveillance system according to the present invention.

### DETAILED DESCRIPTION OF THE INVENTION

In this regard, from years 2001-2006 faculty and students at the Louisiana Universities Marine Consortium monitored inland waters of southern Louisiana. Included in that research was a fifteen-month study of five sites along the Bayou Terrebonne-Bayou Petit Caillou corridor, a 78 km stretch from Thibodaux, La., to Cocodrie, La. These waterways are typically shallow (<2 m), slow moving and are severely impacted by hydrologic modification. Five samplers were used to collect certain water characteristic data (temperature, depth, dissolved oxygen, pH and conductivity) from fixed locations and depths at 30-minute intervals. The samplers were retrieved every two weeks for calibration and data retrieval. Those emplacements have been invaluable in identifying seasonally persistent hypoxia in two locations and the impacts of hurricanes on inland water quality.

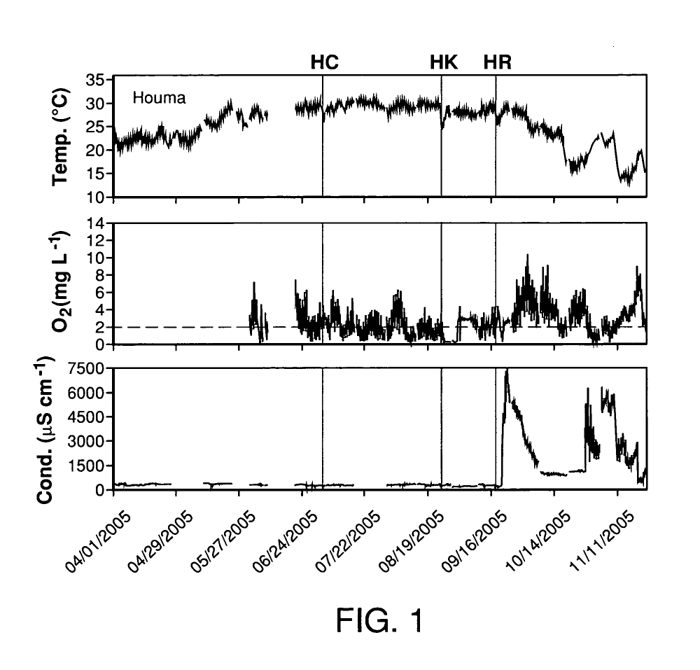

FIG. 1 graphically depicts certain water characteristics detected at one of those sites spanning a period of approximately eight months, i.e., from Apr. 1, 2005 to approximately Dec. 1, 2005. In particular, FIG. 1 presents detected water characteristic data including temperature, dissolved oxygen and conductivity from a site in downtown Houma, La., along Bayou Terrebonne, which is approximately 52 km from the Gulf of Mexico. That site is characterized by persistent hypoxia (i.e., dissolved oxygen (D.O.) <2.0 mg L⁻¹) during the summer months. The initials “HC”, “HK” and “HR” in FIG. 1 refer to Hurricane Cindy, Hurricane Katrina and Hurricane Rita, respectively. As seen in FIG. 1, the effects of storm surge associated with Hurricane Rita (HR) are clearly visible as a nearly 20-fold spike in conductivity that persists for several weeks and re-appears after initial dissipation. Increased conductivity is an indicator of increased ionic content in the water which, in turn, may be reflective of an elevated presence of bio-incompatible substances in the water. A significant limitation of these data, however, is that they are based on samplers that were fixed in location. As a consequence, the samplers were unable to detect significant lateral/horizontal spatial gradients and they could not detect vertical water column stratification because of their fixed sampling depth. Moreover, those studies were restricted to sampling in areas with public automobile access, which precluded sampling at many sites that could be scientifically relevant. It will be appreciated that incorporation of an IMAPS system according to the present invention into such a sampling regime would overcome these testing limitations.

Rowan Pond, located on the Rowan University campus in Glassboro, N.J., USA, has been used for testing of the IMAPS device and for preliminary studies of a small, enclosed freshwater body. The IMAPS device has been deployed in this pond and has been sampled at a minimum of 20 locations and at multiple depths, in which all sensors were used to collect data on water depth, temperature, pH, ammonium, dissolved oxygen, and conductivity. These data are being mapped using a geographical information system (GIS) program to provide a map of the water quality of this small body of water.

The IMAPS device has also been used in a university classroom setting, in which biological sciences majors at Rowan University used the device to test the water quality of Rowan Pond as part of a laboratory exercise for an Environmental Science class in April 2007. These students were asked to answer the question, “What is the water quality of Rowan Pond, and based upon its water quality parameters, is this ecosystem in a healthy condition?”. Students were divided into small groups, in which each group studied one water quality parameter (pH, temperature, etc.). Two students in each group studied the Environmental Protection Agency's water quality standards in the United States, as well as learned about the sources of water pollutants. Two other students in each group collected data on Rowan Pond using the IMAPS. Together, each group will be asked to report back to the class on the health of Rowan Pond based upon their particular water quality parameter, as well as to interpret the meaning of the data collected as to why they indicate (or do not indicate) a healthy ecosystem.

The original concept of the IMAPS was to make it accessible for educational purposes at a variety of educational levels and settings, and this exercise represents the first classroom test of this approach. The students are in the process of analyzing the data collected, but they have already learned about water quality using this hands-on method which also has fostered collaboration and recognition between diverse students on campus (biological sciences and engineering majors).

It is contemplated that the IMAPS system may find beneficial application in other aquatic environments. For example, it is well known that hydrologic modification of watersheds for development or management purposes has altered the natural flow of rivers and streams all over the world. The resulting reduction in water quality, altered patterns of sediment and nutrient transport, and concomitant loss of biological diversity and ecosystem goods and services, are a cause for concern for scientists, resource managers, and policy makers. Restoration of degraded waterways and associated wetlands is now a research priority in the aquatic sciences, and the re-establishment of natural flow regimes is central to these efforts. The IMAPS system is especially well suited for achieving these ends since it may be used to accurately monitor the effects of residential, commercial and industrial landsite development on nearby streams, rivers, ponds, lakes, marshes and other shallow waters and wetlands.

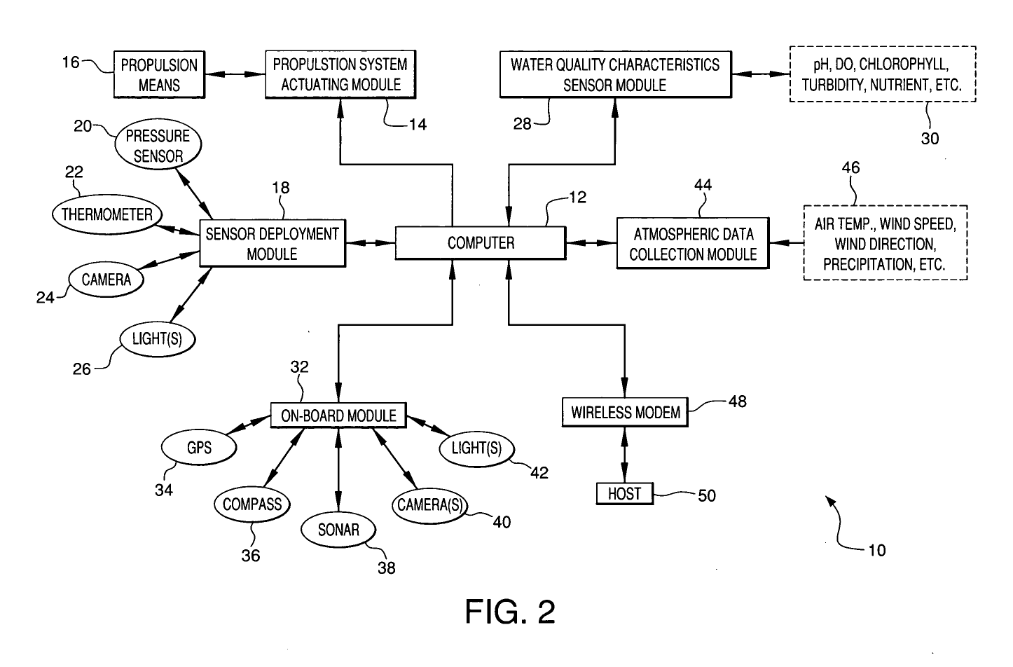

Referring to FIG. 2, there is shown a block diagram of a field agent (or, simply, “agent”) 10 of an interactive mobile aquatic probing and surveillance system according to the present invention. As noted above, a host-agent approach is used to control the agent and to access information gathered by the agent's onboard sensors.

Agent 10 is equipped with several interacting and cooperating units or modules controlled by an on-board computer 12, which computer also monitors the status of the vehicle and its on-board systems. Computer 12 is preferably multifunctional yet compact and lightweight. A presently preferred computer suitable for use as computer 12 would be one based on a Mini-ITX or similar platform. However, any presently known or hereinafter developed computer capable of satisfying the physical and performance requirements of the present invention would be suitable for use as computer 12.

Included among the computer-controlled modules carried by agent 10 is a propulsion system actuating module 14 which, like all of the modules carried by agent 10, is preferably powered by solar-charged and rechargeable batteries. Module 14 is operable to control propulsion means 16, discussed below, for propelling the agent at least about the surface of a body of water and, optionally, about the surface of land.

Agent 10 further carries a sensor deployment module 18 for immersing at least one water characteristic sensor, a multi-sensor package, or other underwater observation equipment, such as, but not limited to, side-scan sonar or underwater video recorder, into and withdrawing the sensor (and/or other equipment) from a body of water. According to a presently preferred embodiment, module 18 comprises a reversible winch and a flexible connector connected to the at least one water characteristic or underwater observation sensor and the winch. According to a still further preferred embodiment, module 18 comprises a later-described sensor holder for carrying: the at least one water characteristic or underwater observation sensor (which sensor(s) may include a pressure sensor 20 and/or a thermometer 22 for sensing water physical characteristic data at the sensor holder such as depth and temperature, at least one water quality characteristic sensor, and/or underwater observation sensor) and, optionally, one or both of a camera 24 and illumination means in the form of at least one light 26 (which, like all lights mentioned hereinafter, may be one or more incandescent lights, halogen lights, light emitting diodes (LEDS), or the like).

Agent 10 preferably carries a water quality characteristic or underwater observation sensor module 28 including at least one sensor for measuring or observing one or more water quality characteristic data 30 including, but not limited to, pH, dissolved oxygen (DO) content, chlorophyll content, turbidity, nutrient content, conductivity, salinity, dissolved carbon dioxide content, dissolved nitrogen content (in the form of one or more of nitrogen, nitrates, nitrites and ammonia), dissolved phosphorus content, heavy metal content, petroleum by-products content, underwater ecology, underwater structure, and other underwater objects. Such sensor(s) may be integrated into multi-sensor packages such as sensor sondes marketed by YSI Incorporated of Yellow Springs, Ohio.

Agent 10 also preferably comprises an On-Board Device Module 32 including one or more of global position system (GPS) telemetry means 34 for enabling the host to monitor the location of the agent, a (preferably digital) compass 36 for determining the heading of the agent, a marine sonar 38 for measuring the depth of water beneath the agent and the presence of nearby underwater obstacles, one or more later-described cameras 40 for visually monitoring areas surrounding the agent, and one or more lights 42 for illuminating areas surrounding the agent.

Agent 10 may also include an atmospheric data collection module 44. Such module may include suitable sensor(s) for detecting one or more atmospheric data 46 including, but not limited to, air temperature, wind speed, wind direction, precipitation, humidity, barometric pressure or any other atmospheric condition that may affect water characteristic sensing results. Still further, agent 10 may include an unillustrated sediment profiler module for measuring geochemistry of intertidal sand/mud flats, marshes and other wetlands areas.

Computer 12 continuously monitors the modules carried by the agent, processes the data sensed thereby and transmits the data, in real time, via a wireless transceiver or modem 48 to a typically land-based host 50. It will be understood that modem 48 may transmit data to the host and receive control commands therefrom at any suitable communication frequency such as, for example, radio frequency.

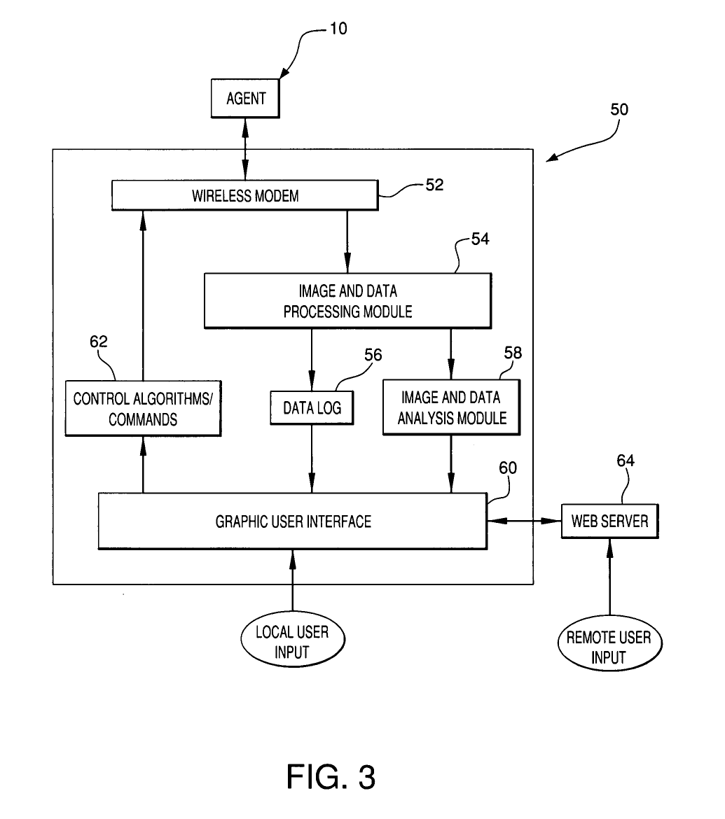

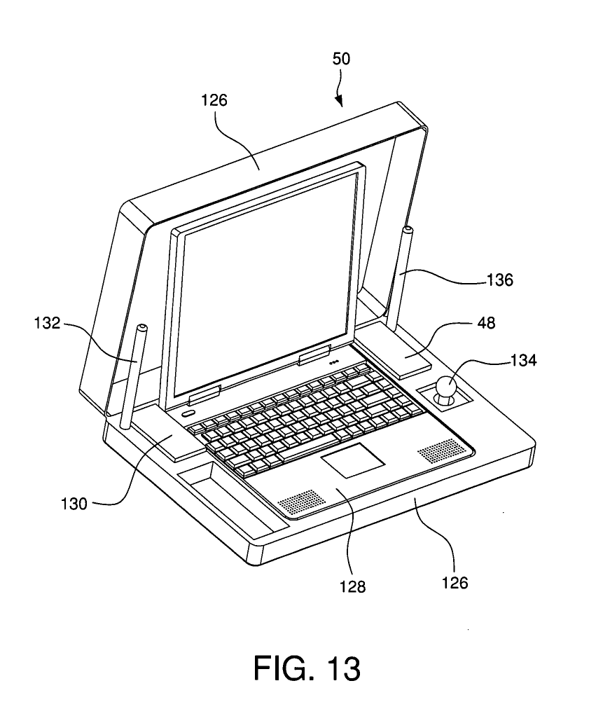

FIG. 3 depicts a block diagram of a host suitable for use in an IMAPS system according to the present invention. The host, identified by reference numeral 50, may comprise any user-interactive computer. According to a presently preferred, although non-limitative embodiment, such a computer may be a laptop computer (see FIG. 13). However, host 50 may be a cellular computing device such as a personal digital assistant (PDA), a cellular telephone or other presently known or hereinafter developed device that is capable of wireless interactive communication with agent 10.

Host 50 comprises a wireless transceiver or modem 52 which transmits control commands to and receives data from agent 10 at a frequency or frequencies compatible with the wireless transceiver or modem 48 of the agent. Data received by modem 52 is transmitted to an image and data processing module 54, which module may be any processor capable of robust image and data processing. Information received and processed by module 54 is passed to a data log 56 and an image and data analysis module 58. Information from data log 56 and image and data analysis module 58 is converted into a form where it may be intelligibly displayed on a screen of a graphical user interface (GUI) 60.

A user may interact with GUI 60 to transmit control commands, preprogrammed algorithms (for path planning, obstacle avoidance, and the like) or other information 62 to agent 10 via wireless modem 52, which information is used by the agent's on-board computer 12 to control the various agent modules and equipment described above. User input to GUI may be local or remote. In the case of a remote user, information is conveyed between the GUI and the remote user via any suitable web server 64.

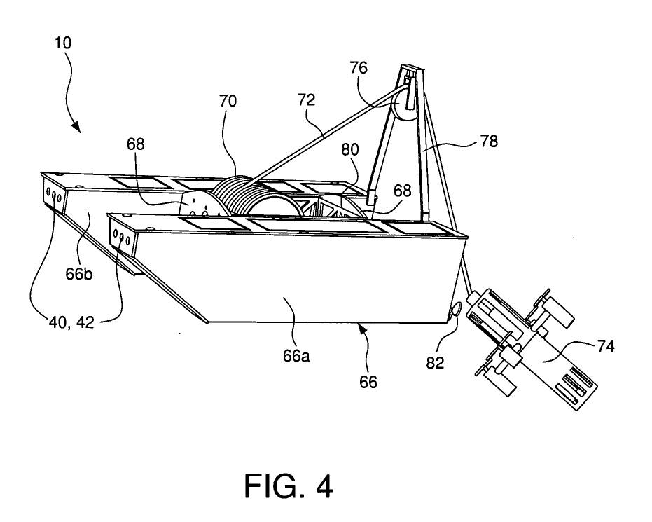

Turning to FIG. 4, there is shown certain externally visible structure and equipment of a first embodiment of an agent 10. In all embodiments, agent 10 comprises a buoyant and non-submersible body 66. The body 66 may be formed from any relatively lightweight, high strength materials such as, for example, aluminum or reinforced plastic. The body may have a single hull (mono-hull) or a multiple hull (multi-hull) construction. As seen in FIG. 4, body 66 may be constructed in the form of first and second hull members 66a and 66b arranged in parallel in the manner of a pontoon. Transverse frame members 68 are desirably affixed to both hull members 66a and 66b to rigidly unite the hull members.

As noted above, agent 10 includes a sensor deployment module 18 for selectively immersing at least one water characteristic sensor into and withdrawing the sensor from a body of water. Any device that is capable of immersing a water characteristic sensor to a depth of up to about 100 feet would be suitable for present purposes. A presently preferred mechanism is a reversible winch, the drum of which is identified by reference numeral 70 in FIG. 4. A flexible connector 72 such as a cable, rope, chain or the like is attached at a first end thereof to drum 70 and at a second end thereof to at least one water characteristic sensor or, as illustrated in FIG. 4, a sensor holder 74 (which is described in detail in connection with FIG. 13). In order to prevent snagging of the flexible connector 72, the connector desirably passes over an idler pulley 76 that is freely rotatably carried by a desirably foldable pulley frame 78 connected to one or both of hull members 66a and 66b. Although not shown, one end of an unillustrated winch drive shaft and an unillustrated reversible winch drum drive motor may be contained within one of the hull members 66a and 66b. And, although not shown, the opposite end of the winch drum drive shaft is supported in a pillow block or similar bushing provided in the opposite hull member. To provide additional support for the winch drum and to impart additional structural rigidity to the body of agent 10, the winch drum is rotatably supported in a winch drum frame 80 that is preferably connected to both hull members 66a and 66b. The forward end or bow of either or both of hull members may be provided with one or more generally horizontally directed, forward facing cameras 40 and/or lights 42 for reasons discussed hereinafter. Lastly, projecting from the rearward or stern end of either or both of hull members 66a and 66b is an underwater propulsion means such as a rotatable propeller 82 for propelling agent 10 about the surface of a body of water (only one of which propeller(s) is shown in FIG. 4, the unillustrated drive motor(s) 16 for which is/are contained in hull member(s) 66a and/or 66b).

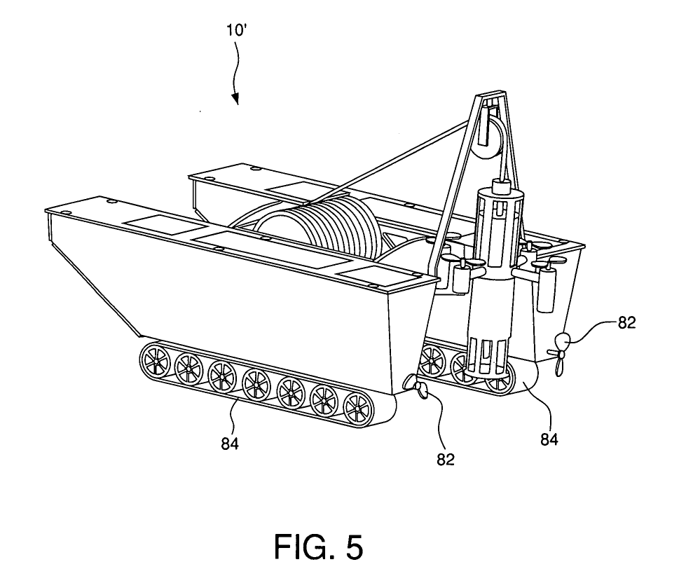

FIG. 5 shows a rear perspective view of an agent 10′ that is in many respects similar to agent 10. As seen in FIG. 5, agent 10 includes two rearwardly projecting propellers 82 for underwater propulsion. In addition, agent 10′ additionally includes land propulsion means in the form of movable tracks 84, similar to military tank tracks, for propelling agent 10′ about a land surface (the unillustrated drive motor(s) 16 for which are contained in hull member(s) 66a and 66b). It will be understood that, in lieu of movable tracks 84, hull members 66a and 66b may be fitted with two or more rotatable ground-contacting driven wheels for propelling agent 10′ about a land surface.

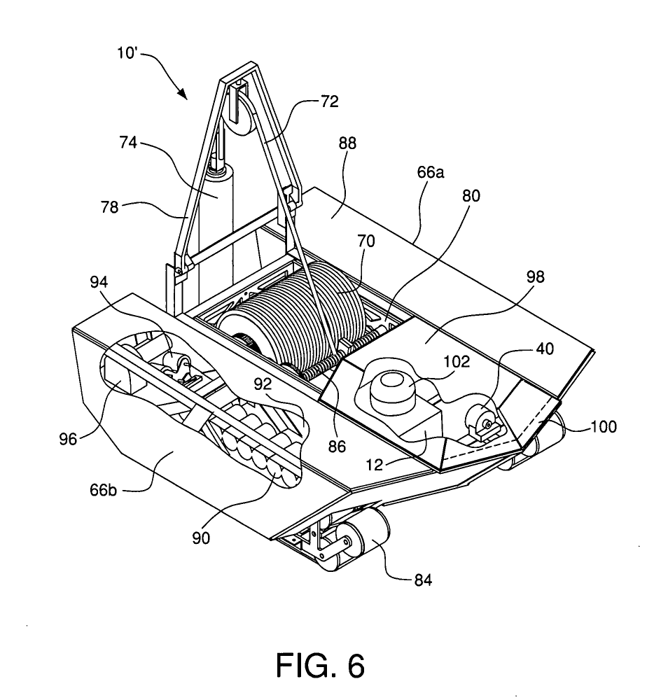

FIG. 6 reveals many additional structural features and operational components of agent 10′ that are not readily visible in FIG. 5. Initially, it will be seen that flexible connector 72 preferably passes around an auto-reversing guide 86 when being dispensed from or wound onto winch drum 70 in order to prevent binding of the flexible connector on the drum. As mentioned above, the agent of the present invention (whether agent 10, agent 10′ or agent 10″ (described below)) is desirably powered by batteries, most preferably solar-powered, rechargeable batteries. Accordingly, the top of at least one (preferably both) of the hull members 66a and 66b is preferably provided with a solar energy collection panel 88 that is sealably yet releasably attachable to the hull member(s). Panel(s) 88 is/are in electrical communication with battery means in the form of one or more batteries in a battery pack(s) 90. The battery pack(s) and other equipment are housed within compartments 92 provided in either or both of hull members 66a and 66b. Additionally, at least one of the compartments 92 includes propulsion drive means for driving the propellers 82 and tracks 84. More particularly, at least one (or, more preferably, both) of the compartments 92 includes propeller drive means 94 in the form of an electric motor and gearing for driving propellers 82 and track (or wheel) drive means 96 in the form of an electric motor and gearing for driving tracks (or wheels) 84. If desired, the propeller and track (or wheel) motors may be reversibly driven.

FIG. 6 also shows an electronics compartment 98 situated atop the forward end or bow of agent 10′. Compartment 98 is preferably sealingly enclosed by a clear cover 100 that may be formed of impact resistant glass or plastic. Housed within compartment 98 is computer 12, a GPS telemetry transceiver 102 and, preferably, a substantially horizontally facing camera 40 with at least a visible, and possibly infrared, spectrum light. Further, although not shown, compartment 98 additionally includes the wireless modem, a video transmitter and, desirably, a marine sonar for detecting water depth and underwater obstacles beneath agent 10′ as well as an unillustrated, preferably digital, compass for determining the heading of the agent.

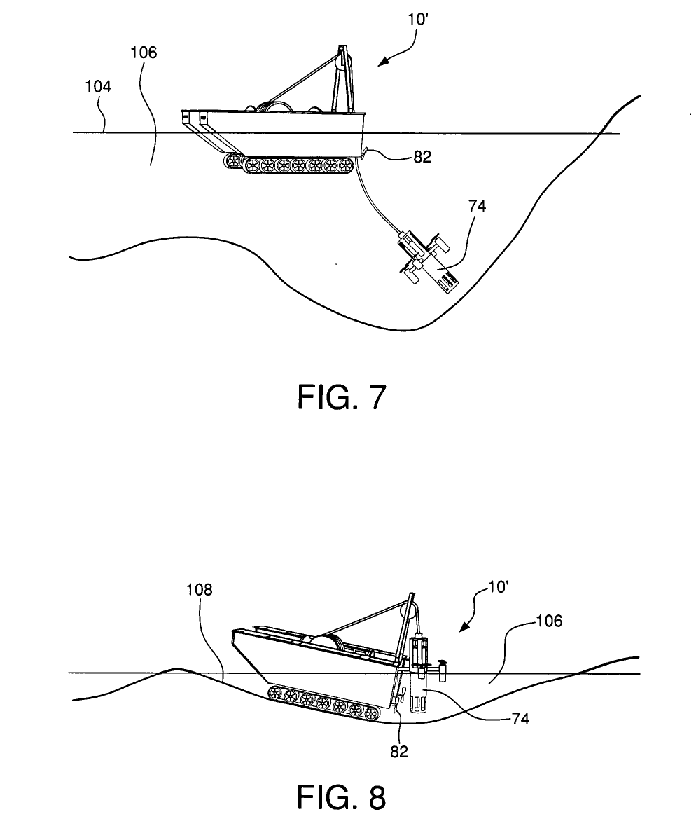

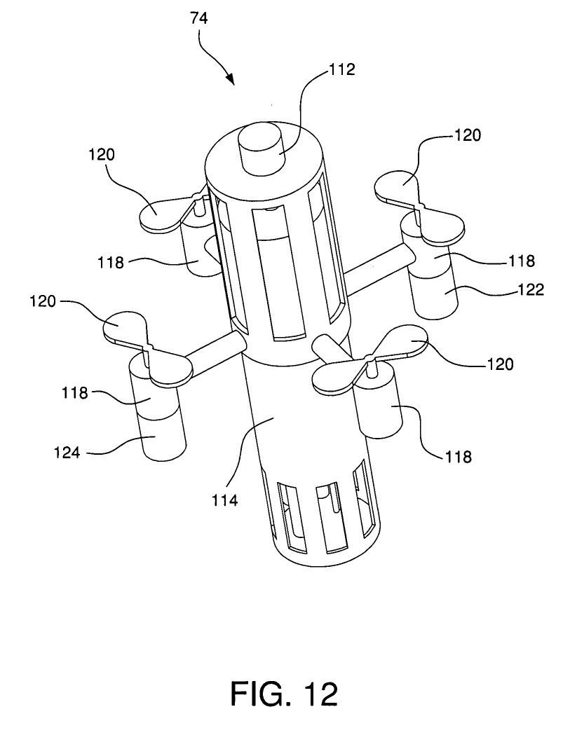

FIGS. 7 and 8 illustrate various deployments of agent 10′. As seen in FIG. 7, agent 10′ is moved to a desired position on the surface 104 of a shallow body of water 106 through remote operation of propeller(s) 82 via propeller control commands entered into host 50 and transmitted thereby to the agent. Once the agent is at the desired water surface location, the user or control software inputs appropriate control commands at the host to cause the winch to lower the at least one water characteristic sensor or, as illustrated, the water characteristic sensor holder 74 to a desired depth. Thereafter, the user enters control commands to activate the at least one sensor and begin the water characteristic monitoring process. If a water characteristic sensor holder 74 is used, the user or control software may input additional commands to control underwater navigation of the sensor holder. In that way, the sensor holder (and the sensor(s) contained therein) may be precisely positioned at a specific underwater location and in a specific orientation, in the manner described in connection with FIG. 12. In addition, the user may also input control commands to operate cameras and/or lights carried by the sensor holder. When testing is completed, the operator instructs the agent to deactivate and raise the at least one sensor, whereby the agent may be navigated to a new water surface location to conduct additional water characteristic monitoring or returned to the host or another selected land location.

Referring to FIG. 8, agent 10′ appears semi-immersed in a shallow body of water 106 and with tracks 84 in contact with a submerged region of an undulating land surface. FIG. 8 illustrates how agent 10′ has the capability to traverse land surfaces as well as to conduct water testing in very shallow waters such as those that might be found in marches and wetlands. When stopped at the location shown in FIG. 8, agent 10′ may be instructed to conduct testing of the shallow water by lowering the at least one water characteristic sensor or sensor holder 74 into the water and conducting the desired monitoring. Upon completion of the testing, the sensor(s) or sensor holder may be completely withdrawn from the water by the winch whereby the agent 10′ may move to another location by actuation of tracks 84 and/or propellers 82 as dictated by the topography of the surrounding terrain.

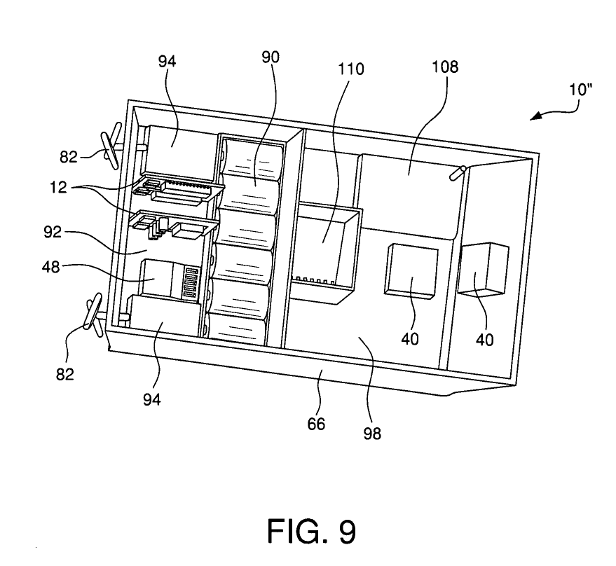

FIG. 9 illustrates a further embodiment of an agent, identified generally by reference numeral 10″, suitable for use in the IMAPS system according to the present invention. Unlike agents 10 and 10′, body 66 of agent 10″ is a mono-hull construction. The overlying cover, preferably a solar energy collection panel, the at least one water characteristic sensor (or sensor holder therefor), and the sensor (or sensor holder) lowering and raising means are omitted for clarity of illustration. It will be understood, however, that all of such equipment is present in agent 10′. Body 66 is divided into a first compartment 92 and a second compartment 98. Compartment includes propeller drive means 94 in the form of an electric motor and gearing for driving propeller(s) 82. It will be understood that any or all of the embodiments disclosed herein may include a single propeller 82 and drive means 94 therefor. In that case, each agent will need a separate steering mechanism for the single propeller or, in the alternative, the hull would need a steerable rudder. In either case, however, it is believed that such additional equipment would complicate the assembly, maintenance and operation of the agent. Compartment 92 may also include track (or wheel) drive means in the form of an electric motor and gearing for driving tracks (or wheels) if the tracks (or wheels) are present. If desired, the propeller motor(s) and track (or wheel) motors, if present, may be reversibly driven.

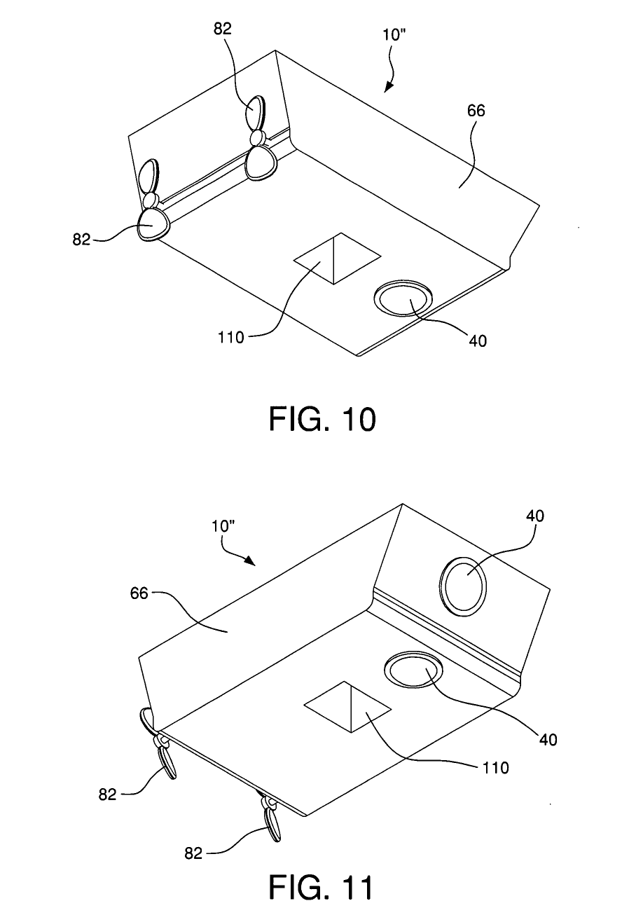

Compartment 92 further includes battery pack 90, computer 12 and wireless modem 48 (although the computer and wireless modem may be situated in compartment 98). Compartment 98 preferably houses forwardly facing and downwardly facing cameras 40 for viewing areas surrounding agent 10″ in front of and beneath the agent, respectively. See also FIGS. 10 and 11. Also housed in compartment 98 are a video transmitter 108 and, preferably, a GPS telemetry transceiver, a marine sonar for detecting water depth and underwater obstacles beneath agent 10″ as well as an unillustrated, preferably digital, compass for determining the heading of the agent. Lastly, as seen in FIGS. 9-11, agent 10″ includes an open bay 110 through which at least one water characteristic sensor (or sensor holder) may be raised and lowered.

Referring to FIG. 12, there is shown a preferred water characteristic sensor holder 74 suitable for use in the IMAPS system of the present invention. Situated atop the sensor holder is a cable harness 112 adapted for electrical connection to unillustrated electrical cables incorporated into or carried by the flexible connector. The electrical cables deliver electricity to and convey sensed data from the at least one water characteristic sensor, or underwater observation equipment, or sensor package sonde 114 received within the sensor holder. Similarly, cable harness 112 includes electrical cables for delivering electricity to at least three or, as illustrated, four laterally displaced thruster motors 118 which drive propellers 120, as well as to at least one optional camera 122 and/or optional pressure sensor 124 carried by the sensor holder. Camera 122 permits the remote user to monitor underwater conditions near the at least one water characteristic sensor or sensor sonde and may incorporate a light (reference numeral 24 in FIG. 2). Pressure sensor 124 enables the user to monitor the depth of the at least one sensor or sensor sonde during a water testing procedure. And, in the event sensor holder 74 is employed, a remote user or control software may input appropriate command controls into the host to activate not only the deployed sensor(s), but also the camera 122 (and optional light) as well as control commands to independently control the thruster motors 118 to precisely position the at least one sensor or sensor sonde at a desired underwater location. Alternatively, the host may transmit pre-programmed navigational algorithms to the agent whereby the sensor holder may be self-adjusting to avoid submerged obstacles.

FIG. 13 illustrates the basic construction of a portable host 50 suitable for use in the IMAPS system. It is preferred that host 50 is portable, but it is not necessary that it be so (e.g., it may be effectively permanently situated in a building). Host 50 desirably includes a water-tight case 126 within which may be received a laptop computer or similar portable computing device 128 which is in electrical communication with: a video receiver 130 and foldable antenna 132 for receiving video communications from the camera(s) carried by the agent and the sensor holder (if present), a joystick 134 which is part of the GUI of the host for controlling the propulsion means of the agent and the sensor holder (if present), and a modem 48 and foldable antenna 136 for transmitting control commands to and for receiving sensed data from the agent. As is known, computer 32 may be powered by AC and/or DC electrical power.

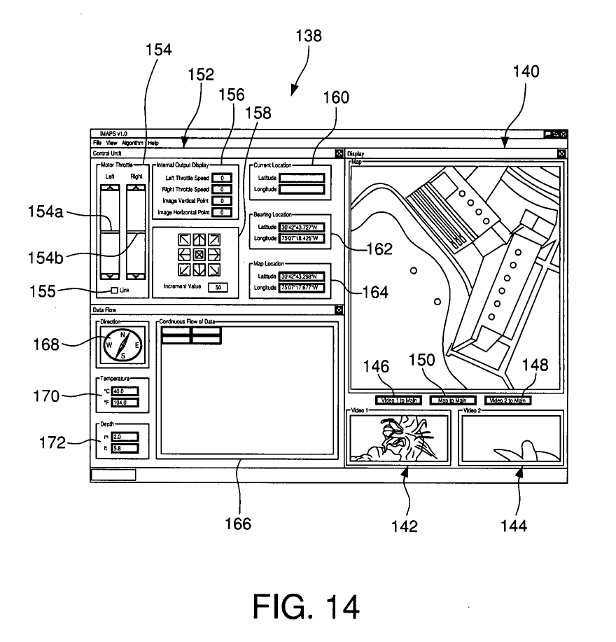

FIGS. 14-16 depict exemplary GUI screen images that may be displayed by host 50. It will be understood that the sensor data, video imagery, agent equipment operational data and other information depicted in FIGS. 14-16 is merely representative, and not limitative, of the types and variety of information that can be observed by a user interacting with the host.

Referring to FIG. 14, there is shown a first host GUI screen display 138 illustrating various imagery and data that is transmittable by the agent in connection with an aquatic study. A prominent portion of screen display 138 is a primary video display window 140. As noted above, the agent of the IMAPS system preferably includes a GPS telemetry transceiver. As is known, GPS telemetry provides precise earth surface location information and may be easily linked to geo-referenced satellite and aerial photographic information. Preferably, therefore, primary video display window 140 enables a user at the host obtain a “bird's eye” view of the geographic area nearby the agent as dictated by the longitudinal and latitudinal positioning coordinates of the agent.

As also noted above, the IMAPS agent preferably includes forwardly and downwardly facing cameras. The images obtained by those cameras are preferably conveyed in real time to the host and displayed on screen display 138. In the screen shot illustrated in FIG. 14, those images are displayed in a pair of secondary display windows 142 and 144. Preferably, screen display 138 permits a user to selectively toggle between the GPS image and the agent camera images for viewing in the primary window 140. In this regard, screen display 138 preferably includes buttons 146, 148 and 150 to permit a user to toggle between the GPS and camera views whereby the most recently selected view becomes the image displayed in the primary video display window 140 while the other views are reduced and displayed to the secondary windows 142 and 144.

Another prominent window of screen display 138 is an agent control window 152. In the illustrated example, agent control window 152 includes several interactive and passive information panels 154, 156, 158, 160, 162 and 164 that enable the user to interact with the host to control certain agent operations or simply monitor certain aspects of the functioning of the agent.

Panel 154 is an interactive panel that enables the user to control throttle of the left and right propeller motors (and track motors if tracks are provided) via left and right slide bars 154a and 154b (or up “↑” and down “↓” arrows) for forward propulsion and steering of the agent. An optional “Link” button 155 may be used to link the control of the left and right throttles to one single input, so the agent will only move straight forward or backward.

Panel 156 is a passive panel that permits a user to monitor left and right motor throttle speed as well as the image vertical (pan) and horizontal (tilt) points

Panel 158 is an active panel that enables a user to manually steer the agent without controlling the throttle directly. The upper left, upper right, lower left and lower right arrows will change the direction of the agent at the increment value inputted by the user. The left and right arrows will change the direction by 90 degrees. The forward and backward arrows speed up or down the agent while the center cross X button will stop the agent completely.

Panel 160 is a passive window that provides the user with the current latitude and longitude of the agent.

Panel 162 is a passive window that provides the user with the current bearing of the agent.

Panel 164 is an active window that provides the user with the destination latitude and longitude of the agent. The values can be manually inputted by the user from the text boxes provided, or interpreted from the curser input on the map on panel 140.

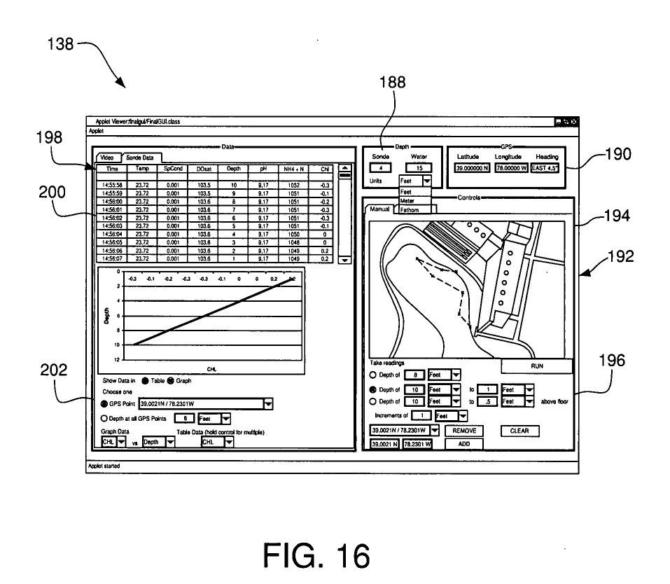

Continuing, panel 166 is a passive panel via which the user may monitor sensor data from the agent in real time. Examples of such data is described in connection with the discussion of FIG. 16.

Panel 168 is a passive panel that contains the image of an analog compass that represents the direction the agent is facing.

Panel 170 is a passive panel that displays the instantaneous surface water temperature (represented in both degrees Fahrenheit and degrees Centigrade.

And, panel 172 is a passive panel that displays the instantaneous water depth beneath the agent.

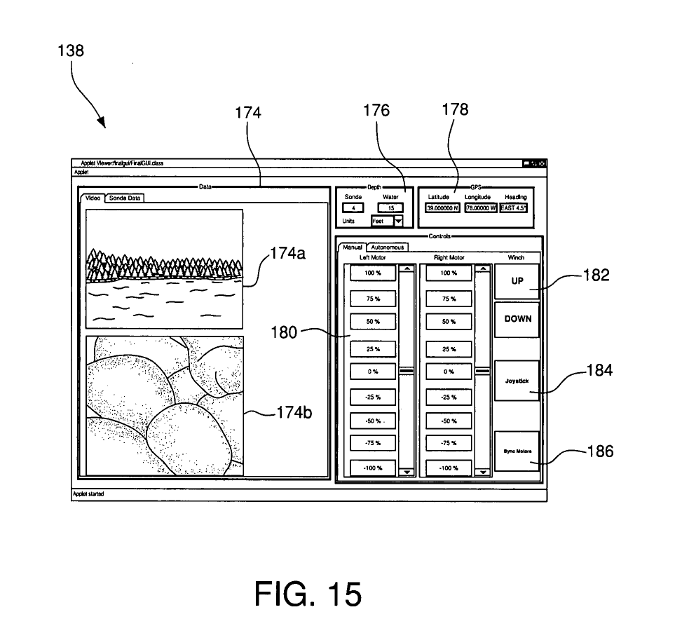

Referring to FIG. 15, screen display 138 displays another video display window and several passive and active panels 174, 176, 178, 180, 182, 184 and 186.

Video display window 174 is a split-screen window displaying, respectively, real time images 174a and 174b conveyed from the forward facing and downward facing cameras.

Panel 176 is a passive panel that simultaneously displays the depth of the water characteristic sensor or sensor holder (sonde) and water (in English, metric of fathom units).

Panel 178 is a passive panel that provides the current latitude and longitude of the agent.

Panel 180 is an interactive panel that enables the user to control throttle of the left and right propeller motors (and track motors if tracks are provided) via a plurality of left and right motor buttons or left and right motor slide bars.

Panel 182 is an interactive panel that enables the user to control the winch to raise and lower the water sensor(s) or sonde.

Panel 184 is an interactive panel that enables the user to control the sensor holder motor thruster joystick.

Panel 186 is an interactive panel that enables the user to synchronize motors so the agent will drive straight forward or backward.

In FIG. 16, screen display 138 displays passive panels 188 and 190 and panels 192 and 198 including combinations of passive data and user-interactive input boxes.

Panel 188 is a passive panel that simultaneously displays the depth of the water characteristic sensor or sensor holder (sonde) and water (in English, metric of fathom units).

Panel 190 is a passive panel that provides the current latitude and longitude of the agent.

Panel 192 includes a video display portion 194 for displaying an aerial or satellite view of the geographic region proximate the agent (or view(s) from the on-board or sensor cameras). In addition, panel 194 includes an interactive portion 196 that enables a user to select sensor readings at desired depths and at desired depth increments with respect to the floor of the water body, as well as agent longitudinal and latitudinal data.

Panel 198 includes a passive portion 200 that displays sensor information in tabular and/or graphical format. Panel 198 additionally includes an interactive portion 202 that enables a user to select the sensor data to be displayed and the format (tabular and/or graphic) in which the data is displayed.

The overall dimensions of a fully-equipped IMAPS system agent according to the present invention (including tracks, track propulsion means and a full complement of electronics) are about 4 feet, by 4 feet by 2 feet. So equipped, the agent weighs about 60 lbs. And, the cost of the system (including agent and host) may range from about $1,000 for a modestly equipped system to about $20,000 for a substantially fully equipped system. Consequently, the IMAPS system is a lightweight, comparatively inexpensive system that may be used for shallow water body bottom mapping and seagrass and other marine flora and fauna mapping, as well as to monitor water conditions in relatively shallow natural or manmade lakes and ponds, bays, marshes and other wetlands, estuaries, slow moving streams rivers, and even manmade drinking water structures such as water tanks, reservoirs and aqueducts.

Although the invention has been described in detail for the purpose of illustration, it is to be understood that such detail is solely for that purpose and that variations can be made therein by those skilled in the art without departing from the spirit and scope of the invention as claimed herein.

What is claimed is:

1. A system for testing characteristics of a body of water comprising:
a host including means for transmitting signals to and for receiving signals from an agent; and
an agent, said agent comprising:
a non-submersible body;
means for propelling said body;
at least one water characteristic sensor; and
means for transmitting signals to and for receiving signals from said host.

2. The system of claim 1 wherein signals transmitted to and received by said agent include agent control commands.

3. The system of claim 2 wherein said agent control commands include navigation control signals for controlling said means for propelling.

4. The system of claim 2 wherein said agent control commands include control signals for controlling said at least one water characteristic sensor.

5. The system of claim 2 further comprising means carried by said body for immersing said at least one water characteristic sensor into and withdrawing said at least one water characteristic sensor from a body of water, wherein said agent control commands include control signals for controlling said means for immersing and withdrawing.

6. The system of claim 5 wherein said means for immersing and withdrawing comprise a reversible winch and flexible connector means connected to said at least one water characteristic sensor and said winch.

7. The system of claim 2 further comprising camera means for visually monitoring field conditions surrounding said agent, wherein said agent control commands include control signals for controlling said camera means.

8. The system of claim 7 wherein said camera means comprise a substantially horizontally facing camera carried by said body for visually monitoring field conditions in front of said agent.

9. The system of claim 7 wherein said camera means comprise a substantially downwardly facing camera carried by said body for visually monitoring field conditions beneath said agent.

10. The system of claim 7 further comprising a sensor holder for holding said at least one water characteristic sensor, wherein said camera means comprise a camera carried by said holder for visually monitoring field conditions near said at least one water characteristic sensor.

11. The system of claim 2 further comprising a sensor holder for holding said at least one water characteristic sensor and means carried by said sensor holder for propelling said sensor holder beneath the surface of a body of water, wherein said agent control commands include control signals for controlling said sensor propelling means.

12. The system of claim 1 wherein signals transmitted to and received by said host include water characteristic data.

13. The system of claim 12 wherein said water characteristic data includes at least one of water physical characteristic data and water quality characteristic data.

14. The system of claim 13 wherein said water physical characteristic data include at least one of water depth and water temperature.

15. The system of claim 13 wherein said water quality characteristic data include at least one of pH, dissolved oxygen (DO) content, chlorophyll content, turbidity, nutrient content, conductivity, salinity, dissolved carbon dioxide content, dissolved nitrogen content (in the form of one or more of nitrates, nitrites and ammonia), dissolved phosphorus content, heavy metal content and petroleum by-products content.

16. The system of claim 1 wherein said agent is not tethered to said host.

17. The system of claim 1 further comprising means for enabling wireless communication between said agent and said host.

18. The system of claim 17 wherein said means for enabling wireless communication include global positioning system telemetry means for enabling said host to monitor the location of said agent.

19. The system of claim 1 further comprising compass means for determining the heading of said agent.

20. The system of claim 2 further comprising light means for illuminating areas surrounding said agent, wherein said agent control commands include control signals for controlling said light means.

21. The system of claim 2 further comprising a sensor holder for holding said at least one water characteristic sensor and light means carried by said sensor holder for illuminating areas near said at least one water characteristic sensor, wherein said agent control commands include control signals for controlling said light means.

22. The system of claim 1 further comprising at least one atmospheric sensor, wherein signals transmitted to and received by said host include atmospheric data.

23. The system of claim 22 wherein said atmospheric data include at least one of air temperature, wind speed, wind direction, precipitation, humidity and barometric pressure.

24. The system of claim 1 wherein said means for propelling said agent include means for propelling said agent about the surface of a body of water.

25. The system of claim 24 wherein said means for propelling said agent about the surface of a body of water comprise at least one motor-driven propeller.

26. The system of claim 1 wherein said means for propelling said agent further comprise means for propelling said agent about the surface of land.

27. The system of claim 26 wherein means for propelling said agent about the surface of land include at least one motor-driven track.

28. The system of claim 1 wherein said means for propelling said agent include means for propelling said agent about the surface of a body of water and means for propelling said agent about the surface of land.

29. The system of claim 1 wherein said body is in the form of a pontoon.

30. A remotely controlled agent for use in a system for testing characteristics of a body of water, said agent comprising:
a non-submersible body;
means for propelling said body;
at least one water characteristic sensor; and
means for transmitting signals to and for receiving signals from a host.

31. A host for wirelessly controlling a non-submersible, self-propelled agent having at least one water characteristic sensor for use in a system for testing a body of water, said host comprising:
a computer;
a video receiver in communication with said computer and an agent;
a wireless transceiver in communication with said computer and an agent;
means in communication with said computer and an agent for controlling propulsion of the agent; and
means in communication with said computer and an agent for controlling the at least one water characteristic sensor.

32. The agent of claim 31 wherein said means for controlling propulsion of the agent and said means for controlling the at least one water characteristic sensor comprise a graphical user interface of said computer.

33. The agent of claim 32 wherein said graphical user interface further comprises a joystick for controlling navigation of the agent.

34. The agent of claim 31 wherein said means for controlling the at least one water characteristic sensor controls immersion of the at least one water characteristic sensor into and withdrawal of the at least one water characteristic sensor from a body of water.

35. The agent of claim 34 wherein said means for controlling for immersion of the at least one water characteristic sensor into and withdrawal the at least one water characteristic sensor from a body of water comprise a graphical user interface of said computer.
